(19) United States
(12) Patent Application Publication
(10) Pub. No.: US 2026/0206612 A1
(43) Pub. Date: Jul. 16, 2026

(54) ELECTRICALLY CONDUCTIVE VIAS HAVING END CAPS

(71) Applicant: SAMTEC, INC., New Albany, IN (US)

(72) Inventors: Mark CRAIN, New Albany, IN (US); Christopher David BOHN, New Albany, IN (US); Abderrazzak FAIZ, New Albany, IN (US); Zach LARIMORE, New Albany, IN (US); Troy Benton HOLLAND, New Albany, IN (US); Nathan ROBERTSON, New Albany, IN (US)

(21) Appl. No.: 19/134,300

(22) PCT Filed: Nov. 30, 2023
(86) PCT No.: PCT/US2023/081766

§ 371 Date: May 30, 2025

Related U.S. Application Data
(60) Provisional application No. 63/385,525, filed on Nov. 30, 2022.
(60) Provisional application No. 63/600,531, filed on Nov. 17, 2023.

(51) Int. Cl. H10W 70/05

(52) U.S. Cl. CPC H10W 70/095

(57) ABSTRACT

An electrically conductive component includes a substrate and an electrically conductive via that can include an electrically conductive coating bonded to an internal surface of the substrate, a fill that is surrounded by the electrically conductive coating, and first and second electrically conductive end caps that hermetically seal opposed ends of the vias.

### CROSS-REFERENCE TO RELATED APPLICATIONS

This application claims priority to U.S. Patent Application No. 63/385,525 filed Nov. 30, 2022, and U.S. Patent Application No. 63/600,531 filed Nov. 17, 2023, the disclosures of each of which are hereby incorporated by reference as if set forth in its entirety herein.

### BACKGROUND

2.5-D and 3-D packaging is a novel implementation of an already well-established concept that previously was referred to as MCMs (multichip modules). A thin glass, silicon or other dielectric substrate material is created having a plurality of holes or vias that are metalized in such a manner as to create an electrical path. The integrated circuit packaging industry refers to these interconnection substrates as interposers. Holes fabricated into the interposer are typically very small, for example, 5 μm to 100 μm in diameter and 50 μm to 500 μm in depth. The number of holes per square centimeter may be in the hundreds or even thousands. Following the processing necessary to fabricate these holes, the next step is to metalize the hole to provide for an electrically conductive pathway from one circuit plane or substrate to another.

Current state of the art processes known as “copper electroplate” methods for metalizing interposer through holes and blind holes are very costly and generally lack manufacturing scalability. The metallization methods include a combination of Physical Vapor Deposition (PVD) or evaporative or sputtering deposition to form an adhesion, barrier, and or seed layer followed by electroplating, typically of copper. The equipment necessary to run these processes is expensive and difficult to scale to high-throughput manufacturing. For instance, the copper electroplating process can typically take 1 to 8 hours for each substrate, depending on substrate size, hole diameter and aspect ratio. The electroplating process requires each substrate to be electroplated in an individual process cell having sophisticated analytical and dispensing controls and precise chemical species and electrical field distribution across the substrate.

Electroplated copper deposits extending beyond the surface of the substrate are referred to in the art as “over burden.” To level the copper electroplated deposit flush or planar with the substrate surface typically requires a secondary process using chemical-mechanical polishing (CMP). Maintenance and operation of the CMP process requires highly skilled technicians for monitoring and control to achieve consistent results. Copper is a relatively soft metal and methods used to mechanically remove the excess copper are constrained by the loading of the soft copper into the abrasive material.

A second method of depositing copper or other electrically conductive materials into via holes in interposer substrates utilizes metallic inks. The metallic inks typically are formulated using metal powder dispersed in a bonding resin or other polymer for ease of hole filling and a capping agent to prevent the metallic powder from oxidizing. After the holes are filled with the metallic ink along with the resin or capping agents, it is necessary to volatize all organic materials and remove them from the metallic powder to achieve reasonable electrical conductivity. Temperatures required for volatizing these organic compounds may reach 400° C. to 800° C. The carbon ash left after volatizing the organic compounds may negatively impact optimal conductivity and leave significant potential for discontinuous filling of the hole. The potential for discontinuous or electrically open areas in the filled hole or via is unacceptable.

Most of these processes work only on a very limited hole length/width ratio, and narrow or extra wide holes are very difficult to manufacture in a consistent manner or achieve hermeticity.

### SUMMARY

In one example, an electrical component can include a substrate defining a first surface and a second surface opposite the first surface, and an internal surface that defines an electrically conductive via that extends from the first surface to the second surface. The via can include an electrically conductive coating bonded to the internal surface of the substrate, and an electrically conductive end cap that is bonded to the electrically conductive coating so as to hermetically seal the via.

In another example, the end cap can be a first end cap that extends from a respective portion of the electrically conductive coating substantially to the first surface, and the via comprises a second end cap that extends from a respective portion of the electrically conductive coating substantially to the second surface.

In another example, the electrically conductive via can further include a fill that is surrounded by the electrically conductive coating. The fill can be electrically nonconductive. Alternatively, the fill can be electrically conductive.

### BRIEF DESCRIPTION OF THE DRAWINGS

The foregoing summary, as well as the following detailed description of illustrative embodiments of the present application, will be better understood when read in conjunction with the appended drawings. For the purposes of illustrating the locking structures of the present application, there is shown in the drawings illustrative embodiments. It should be understood, however, that the application is not limited to the precise arrangements and instrumentalities shown. In the drawings:

FIG. 1A is a schematic cross-sectional view of a substrate showing a plurality of holes;

FIG. 1B is a schematic cross-sectional view of the substrate of FIG. 1A, wherein the holes are metallized to produce electrically conductive vias;

FIG. 2A is a schematic cross-sectional view of an electrically conductive via of FIG. 1B;

FIG. 2B is an enlarged scanning electron microscope (SEM) image of a first portion of the via of FIG. 2A, wherein a second portion of the via is a reproduction of the SEM image of the first portion of the via to illustrate various features of the via;

FIG. 3 is a view showing a method of producing the via illustrated in FIG. 2A;

FIG. 4 is a schematic cross-sectional view of an electrically conductive via of FIG. 2A, but showing protruding end caps;

FIG. 5A is a sectional view of a substrate having an electrically conductive via in another example; and

FIG. 5B is a side view of first and second vias joined to each other in one example.

### DETAILED DESCRIPTION

A description of an embodiment with several components in communication with each other does not imply that all such components are required. To the contrary, a variety of optional components may be described to illustrate a wide variety of possible embodiments of one or more of the disclosures and in order to more fully illustrate one or more aspects of the present disclosure. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Further still, some steps illustrated in a method can be omitted. Moreover, the illustration of a process by its depiction in a drawing does not imply that the illustrated process is exclusive of other variations and modifications thereto, does not imply that the illustrated process or any of its steps are necessary to one or more of the disclosure(s), and does not imply that the illustrated process is preferred. Also, steps are generally described once per embodiment, but this does not mean they must occur once, or that they may only occur once each time a process, method, or algorithm is carried out or executed. Some steps may be omitted in some embodiments or some occurrences, or some steps may be executed more than once in a given embodiment or occurrence. Further, some of the steps can be eliminated in some embodiments. Further still, other steps can be added as desired.

Techniques and mechanisms described or referenced herein will sometimes be described in singular form for clarity. However, it should be appreciated that particular embodiments may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of embodiments of the present disclosure in which, for example, functions may be executed out of order from that shown or discussed, including substantially concurrently or in reverse order, depending on the functionality involved, as would be understood by those having ordinary skill in the art.

The term “substantially,” “approximately,” derivatives thereof, and words of similar import as used herein with respect to a value, size, shape, direction, or location, can include the stated value, size, shape, direction, and location, and variances up to 10% of the stated value or shape, or location, including 8%, 5%, 3%, 2%, and 1%, unless otherwise indicated.

The singular terms “a,” “an,” and derivatives thereof as used herein can apply with equal force and effect to “at least one,” “one or more,” and “plurality” unless otherwise indicated. Further, the plural term “plurality” and derivatives thereof can apply with equal force and effect to the singular “a” and “an,” and to “at least one” and “one or more” unless otherwise indicated.

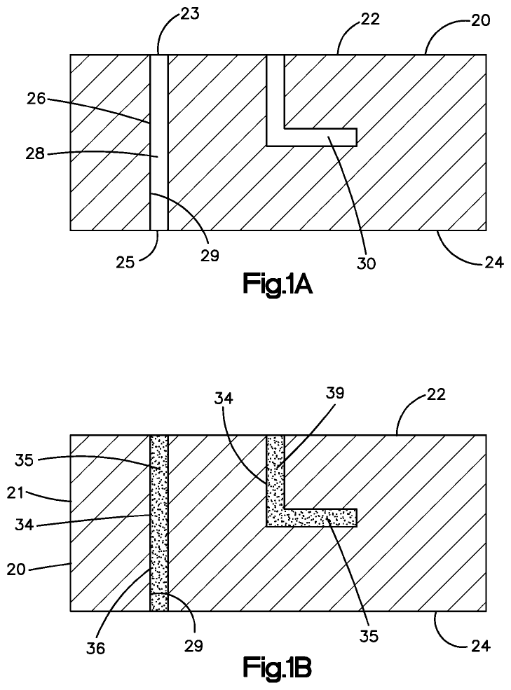

With initial reference to FIG. 1A, a substrate 20 defines opposed outer surfaces including a first surface 22 and a second surface 24 opposite the first surface along a direction. The first and second surfaces 22 and 24 can be external surfaces of the substrate 20. The substrate 20 further includes a plurality of internal surfaces 29 that define a respective plurality of holes 26. The holes 26 extend from the first surface 22 toward the second surface 24 along a central axis 31 oriented along an axial direction. For instance, the holes 26 can extend from the first surface 22 to the second surface 24 along the central axis 31. The holes can thus be elongate along the central axis 31. The substrate 20 can be cut into wafers of 150 mm, 200 mm, or 300 mm in diameter, but it is recognized that the substrate 20 can define any suitable diameter or other maximum dimension as desired. Thus, the term “diameter” can be used interchangeably with the term “maximum cross-sectional dimension” to denote that the structure of reference need not be circular unless otherwise indicated.

The holes 26 can have any suitable diameter as desired. For instance, the holes 26 can have a diameter or other cross-sectional dimension perpendicular to the central axis 31 in a range from approximately 10 μm to approximately 25 μm. It should be appreciated, of course, that range of the diameter or other cross-sectional dimension can have no upper limit. The holes 26 can have a depth along their respective central axes within a range from approximately 100 μm to approximately 500 μm. The holes 26 can have an aspect ratio between hole diameter and hole depth that is unlimited. Additionally, a plurality of different hole diameters may be placed in the same substrate. The holes 26 can be conical in shape, cylindrical in shape, hourglass shaped, or can define any suitable shape along their length. The holes 26 can be arranged in one or more hole arrays as desired. Thus, the substrate 20 can define one or more arrays spaced with each other at any suitable distance suitable for cutting the glass and separating the arrays into discrete components of the substrate 20. While glass substrates can have particular applicability to certain end-use applications, it should be appreciated that substrate 20 can be a glass substrate, a silicon substrate, a silica substrate, a quartz substrate, a ceramic substrate, a sapphire substrate, or any organic substrate or any other substrate of any suitable alternative material as desired. When the substrate 20 is a glass substrate, the glass can be substantially lead-free, including lead-free, in one example. Thus, the substrate 20 can be biocompatible as desired. In other examples, the glass can include lead.

The term substantially “lead-free,” derivatives thereof, and phrases of like import as used herein can refer to a quantity of lead that is in accordance with the Restriction of Hazardous Substances Directive (RoHS) specifications. In one example, the term “lead-free,” “free of lead,” and derivatives thereof can mean that the quantity of lead is less than 0.1% by weight, including 0% by weight. Alternatively or additionally, the term “lead-free,” derivatives thereof, and phrases of like import as used herein can mean that the quantity of lead is less than 0.1% by volume. In another example, the term “lead-free,” derivatives thereof, and phrases of like import as used herein can mean that the quantity of lead is less than 100 parts per million (ppm).

At least one or more of the holes 26 can be configured as a through hole 28 that extends through the substrate 20 from the first surface 22 to the second surface 24. Thus, the first surface 22 defines a first opening 23 to the through hole 28, and the second surface 24 defines a second opening 25 to the through hole 28. Otherwise stated, the through hole 28 defines a first end at the first opening 23 at the first surface 22, and a second end at the second opening 25 at the second surface 24. Thus, both the first and second ends of the through holes 28 are open to the outer perimeter of the substrate 20. The through hole 28 can be straight and linear from the first opening 23 to the second opening 25. Alternatively, one or more portions of the through hole 28 can be angled, bent, or define any suitable alternative non-straight shape.

Alternatively or additionally, at least one or more of the holes 26 can be configured as a blind hole 30 that can extend from one of the first and second surfaces 22 and 24 toward the other one of the first and second surfaces 22 and 24. Further, the blind hole can terminate at a location spaced from the other of the first and second surfaces and 22 and 24. Thus, the blind hole 30 is open to one external surface of the substrate 20 at a first end, and internally closed by the substrate 20 at a second end opposite the first end. Otherwise stated, the first terminal end of the blind hole 30 extends to one of the first and second surfaces 22 and 24, and the second terminal end of the blind hole 30 is disposed between the first and second surfaces 22 and 24. It is recognized, however, that the second terminal end of the blind hole 30 can terminate at another hole 26, and thus can be in communication with both the first and second openings 23 and 25. Further, the blind hole 30 can be linear, or can have one or more segments that are angled with respect to each other. One or more of the segments can define a lateral segment. The substrate 20 can include a sacrificial hole that extends from the blind hole 30 to an outer surface of the substrate 20. For instance, when the blind hole 30 is open, either directly or through another hole, to the first surface 22 of the substrate 20, the sacrificial hole can extend from the closed end of the blind hole 30 to the second surface 24.

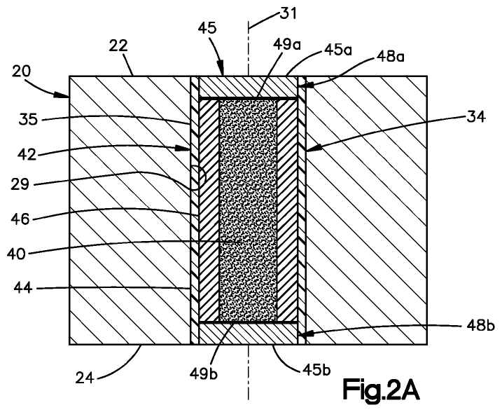

Referring now to FIG. 1B, one or more of the holes 26 can contain an electrical conductor 35 to define an electrically conductive via 34 between the first end of the hole and the second end of the hole. In some examples, the electrical conductor 35 can be defined by one or more electrically conductive materials such as one or more metals arranged as one or more layers. For instance, the electrical conductor 35 can include an annular electrically conductive coating 42 that is bonded to the internal surface 29 of the substrate 20, and at least one electrically conductive end cap 45, such as first and second end caps 45a and 45b disposed at the first and second ends of the via 34 (see FIG. 2A). The electrically conductive coating 42 can be substantially circular in cross-section, oval rectangular, or can define any alternative regular or irregular shape as desired. In some cases, the length of the electrically conductive coating 42 can be shorter than the length of the interior surface 29 of the substrate 20.

It is thus appreciated that the electrically conductive via 34 can extend from the first end of the hole to the second end of the hole along the central axis 31. In this regard, the central axis 31 of the hole 26 can define the central axis 31 of the via 34. Further, the first and second ends of the hole 26 can define the first and second ends of the via 34. The electrical conductor 35 can at least partially define the electrically conductive via 34. As will be appreciated from the description below, additional materials can be disposed in the hole 26 so as to further define the electrically conductive via 34. For instance, the electrically conductive vias 34 can include an internal fill material 40 that is disposed in the hole 26 inside the electrical conductor 35. Thus, the electrical conductor 35 can surround the fill material 40. The fill material 40 can be electrically nonconductive or electrically conductive as desired. The substrate 20 having one or more electrically conductive vias 34 can be referred to as an electrical component. The fill material 40 can extend continuously along a majority up to an entirety of the length of the hole 26, and thus of the resulting via 34, wherein the length is defined by a direction that defines the central axis of the hole 26, and thus of the via 34. For instance, the fill material 40 can extend continuously along a distance of at least 75%, such as at least 80%, such as at least 85%, such as at least 90%, such as at least 95% of the length of the hole 26, and thus of the resulting via 34.

In particular, the through hole 28 that contains the electrical conductor 35 can be said to define a through via 36. The blind hole 30 that contains the electrical conductor 35 can be said to define a blind via 39. Thus, the term “via” and derivatives thereof as used herein can refer to one or both of the through via 36 and the blind via 39. The electrical conductor 35 can extend continuously from the first end of the via 34 to the second end of the via 34. Thus, the electrical conductor 35 can define an electrically conductive path along the via 34 in the direction that extends between first end of the via and to the second end of the via. For instance, the electrically conductive path can be defined from the first end of the via 34 to the second end of the via 34. In this regard, it is appreciated that the first and second ends of the via 34 can be defined by the first and second openings 23 and 25 when the via 34 is a through via 36. In certain examples, the electrically conductive vias 34 can be referred to as metallized vias 34. Similarly, the substrate 20 can be referred to as a metallized substrate.

The substrate 20 can include at least one or more electrically conductive redistribution layers. The redistribution layers can be applied to one or both of the first surface 22 and the second surface 24. The redistribution layers can extend over at least one of the electrically conductive vias 34, and are thus in electrical communication with the electrical conductor 35. In one example, the substrate 20 can be configured as an electrical interposer configured to make electrical connections at each of the first surface 22 and the second surface 24 at electrical contacts that are in electrical communication with each other through the electrically conductive via 34.

As will be appreciated from the description below, the electrically conductive vias 34 can be suitable for conducting both direct current (DC) and radiofrequency (RF) current. The electrical conductor 35 can extend in the via 34 from the first end of the via to the second end of the via, such that the electrically conductive material defines an electrically conductive path from the first end to the second end. Thus, when the via 34 is a through via 36, the electrical conductor 35 can define an electrically conductive path substantially from the first surface 22 of the substrate 20 substantially to the second surface 24.

Referring now to FIGS. 2A-2B, the via 34 will now be described in more detail. The via 34 can include the electrical conductor 35 disposed in the hole 26. The electrical conductor 35, and thus the substrate 20, can include an electrically conductive coating 42 disposed on the internal wall 29. The electrically conductive coating 42 can be bonded or otherwise adhered to the internal surface 29. The coating 42 can extend along the internal surface 29 between the first surface 22 and the second surface 24. The electrically conductive coating 42 can extend across a midline of the internal wall 29 that is equidistantly spaced from each of the first surface 22 and the second surface 24. In one example, the electrically conductive coating 42 extends from the first surface 22 to the second surface 24. The electrically conductive coating 42 can define a cylinder or alternatively configured, depending on the cross-sectional shape of the internal surface 29, that contains the fill material 40.

The electrically conductive coating 42 can include at least one metal that extends along the substrate 20, and in particular to the internal surface 29, so as to define an electrically conductive layer structure. In one example, the layer structure can include at least one metal that is vapor deposited onto the substrate 20 so as to define an electrically conductive first layer 44 which can be a first metal layer. It should be appreciated that the first layer 44 can be applied to the internal surface 29 using any suitable alternative deposition or application technique. The first layer 44 can extend along the internal surface 29 between the first surface 22 of the substrate 20 and the second surface 24 of the substrate 20, such as from the first surface of the substrate 20 to the second surface 24 of the substrate 20. The electrically conductive first layer can further be said to extend from the first terminal end of the substrate 20 to the second terminal end of the substrate 20. The first layer 44 thus bonds to the substrate 20, and in particular to the internal surface 29.

The electrically conductive coating 42, and thus the layer structure, can further include an electrically conductive second layer 46 that is bonded to the electrically conductive first layer 44. The electrically conductive second layer 46 can be defined by at least one second metal that is bonded to the electrically conductive first layer. The at least one second metal can be the same as or different than the at least one first metal of the first layer 44. The first layer 44 can be disposed between the internal surface 29 and the second layer 46. The second metal can be vapor deposited onto the first metal layer 44 to produce the second layer 46. In this regard, the first layer 44 can be referred to as an adhesion layer, such as an internal surface adhesion layer. The first metal can be at least one of copper, gold, silver, platinum, titanium, aluminum, nickel, tungsten, molybdenum, zinc, barium, boron, palladium, or any suitable alternative material as desired. The first layer 44 can have any suitable thickness as desired along a direction perpendicular to the central axis of the via. In one example, the thickness of the first layer 44 ranges from approximately 1 nanometer (nm) to approximately 1000 nm. For instance, the thickness of the first layer 44 can range from approximately 1 nanometer (nm) to approximately 50 nm. In one example, the thickness can range from approximately 5 nm to approximately 10 nm.

The second layer 46 can be referred to as a bonding layer that bonds to the fill material 40. The second metal of the second layer 46 can be a transition metal. For instance, the second metal can be at least one or more of copper, gold, silver, platinum, titanium, aluminum, nickel, tungsten, molybdenum, zinc, barium, boron, palladium, or any suitable alternative material as desired. Thus, the coating, including the first and second layers 44 and 46, and thus the first and second metals, can be defined by the same single metal in some examples. Otherwise stated, the coating can include a single metal that bonds to the internal surface of the glass substrate, for instance using vapor deposition, and is configured to bond to the fill material 40. It should be appreciated that the layer structure can include either or both of the electrically conductive first and second layers 44 and 46. As will be described in more detail below, a portion of the hole 26 can be occupied by the layer structure, and at least a portion up to an entirety of a remaining portion of the hole 26 can be occupied by the internal fill material 40 that is bonded to the layer structure.

The second layer 46 can be thicker than the first layer 44 in some examples along a direction perpendicular to the central axis of the via. For instance, the second layer 46 can have a thickness within a range from approximately 200 nm to approximately 5 microns. For instance, the thickness can range from approximately 0.5 micron to approximately 2 microns. In other examples, it is recognized that the first layer 44 can bond directly with the fill material 40, and the via 34 can thus be devoid of the second layer 46.

The electrically conductive via 34 can further include the fill material 40 that is disposed in the hole 26 and surrounded by the electrically conductive coating 42. The fill material 40 extends between the first and second ends of the via. For instance, the fill 40 can extend from the first end to the second end. Thus, the fill 40 can extend from the first surface 22 to the second surface 24. The electrically conductive coating 42 can surround the fill 40. Thus, when the electrically conductive coating 42 includes the first and second layers 44 and 46, the second layer 44 can surround the fill 40 and can bond to the fill 40. In other examples, when the electrically conductive coating 42 includes only the first layer 44 and not the second layer 46, the first layer 42 can surround the fill and can bond to the fill 40. In one example, the fill 40 can be electrically nonconductive.

For instance, the fill 40 can be defined by an electrically nonconductive paste that is introduced into the hole 26 in the electrically conductive coating 42. The electrically nonconductive paste can be introduced into the hole 26 and subsequently cured so as to define the fill 40. For instance, the fill 40 can be sintered, which causes the fill to solidify and bond to the electrically conductive coating 42. For instance, the fill 40 can bond to the second layer 46. In other examples, for instance if the electrically conductive coating includes only the first layer 44, the fill 40 can bond to the first layer 44.

In one example, the electrically nonconductive paste can include a viscous carrier, and a plurality of particles supported by or otherwise disposed in the viscous carrier. For instance, the particles can be suspended in the viscous carrier. The particles can be electrically nonconductive. In one example, the particles can be made of silica. The carrier can be a resin. The resin can be a thermally curable resin, and can thus transform from a viscous state to a hardened state. In some examples, the carrier can be a dielectric carrier. In one example, the carrier can be an epoxy dielectric carrier. The carrier can be thermally curable. One example of such an epoxy is Duralco 4460 commercially available from Cotronics Corp. having a principle place of business in Brooklyn, NY. Another example is Duralco 4701 commercially available from Cotronics Corp. It is recognized that any suitable epoxy can be used. The epoxy can have any suitable curing temperature as desired. In one example, the curing temperature of the epoxy is approximately 125 degrees Celsius in air at atmospheric pressure. In other examples, the carrier can be a polyimide dielectric carrier. It should be appreciated, of course, that the carrier can be any suitable material that can be blended in a liquid state with the particles prior to curing to a solid rigid state. In other examples, the carrier can be a sodium silicate, also known as water glass. For instance, the carrier can be acquired under the tradename MB600 commercially available from Masterbond, Inc having a principal place of business in Hackensack, NJ. The carrier can be cured thermally or under ultraviolet light. For instance, in some examples the resin can be cured upon exposure to ultraviolet light. The particles can fuse to each other during curing, such that the particles are fused to each other after curing, and the fill 40 can remain electrically nonconductive after curing.

The paste can have a dynamic viscosity that is in a range from approximately 1 centipoise (cP) to approximately 40,000 cP. For instance, the range can be from approximately 1.5 cP to approximately 1,000 cP. In one example, the range can be from approximately 30 cP to approximately 300 cP. In another example, the range can be from approximately 1.8 cP to approximately 15 cP. For instance, the range can be from approximately 1.9 cP to approximately 5 cP. It is recognized that low viscosity pastes allow for large quantities of electrically conductive material to be included in the paste while preventing the paste from reaching a thickness level that prevents its ability to be filled into the one or more holes of the substrate.

In another example, the paste can be electrically conductive. In particular, the fill can include a plurality of electrically conductive particles disposed in the carrier. The electrically conductive particles can, for instance, be one or more up to all of copper particles, gold particles, silver particles, platinum particles, titanium particles, aluminum particles, nickel particles, tungsten particles, molybdenum particles, zinc particles, barium particles, boron particles, palladium particles, or any suitable alternative particles. Metals described herein can include compounds thereof, alloys thereof and oxides thereof. The particles can be present in sufficient quantity such that the paste is electrically conductive prior to sintering when the paste is in its viscous form. The particles fuse to each other during sintering, such that the fill 40 remains electrically conductive after sintering. Alternatively, the quantity of particles can be insufficient to render the paste electrically conductive prior to sintering when the paste is in its viscous form. However, the particles fuse with each other during sintering, which causes the fill 40 to be electrically conductive.

It should therefore be appreciated that both the electrically conductive coating 42 and the fill 40 can be lead-free. Thus, the substrate 20 can be biocompatible. The term “lead free” can mean substantially free of lead including lead oxides, lead alloys, lead compounds, and all lead constituents. Thus, the substrate 20 is usable in applications where biocompatibility is desired. In some examples the via 34 can include only the fill 40 and the electrically conductive coating 42. The fill can include only the carrier and the electrically conductive particles or electrically nonconductive particles. The carrier can provide adhesion to the electrically conductive coating 42 during when the paste is sintered.

In some examples, the particles can occupy from approximately 10% up to approximately 90% of the volume of the paste, and thus of the resulting fill 40 and via 34. The remaining volume can be occupied by the carrier. For instance, the particles can occupy between approximately 50% to approximately 85% of the volume of the paste, and the remaining approximately 15% to approximately 50% of the volume of the paste can be occupied by the carrier. It has been found that less viscous carriers can allow for higher percentages of particles by volume. The paste can have a viscosity from about 30 Pascal Seconds (Pa s) to about 400 Pa s.

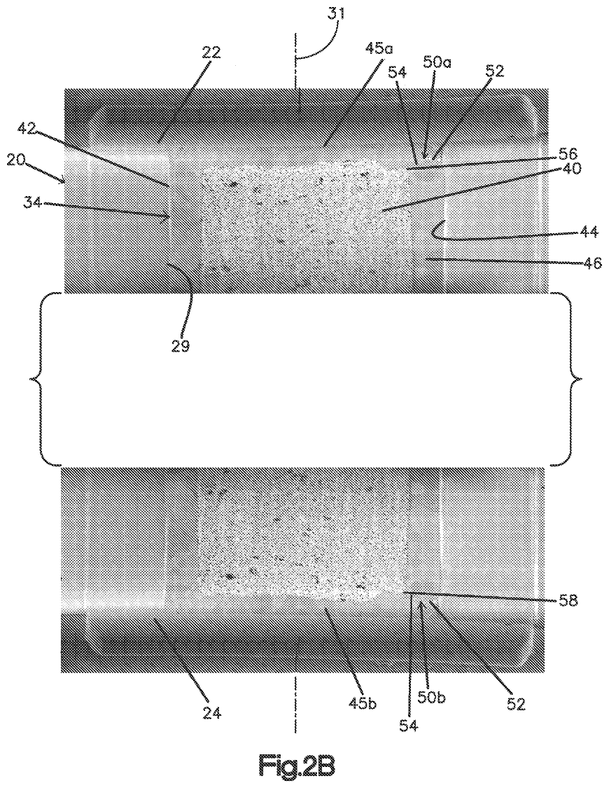

With continuing reference to FIG. 3, during fabrication, the holes 26 can be created, for instance, by laser ablation. Alternatively, the substrate 20 can be provided with the holes 26 preformed. Next, the coating 42 can be applied to the substrate 20. In particular, the first electrically conductive layer 44 can be applied to the internal surface 29, and optionally either or both of the first and second surfaces 22 and 24, by a vapor deposition process. For instance, the vapor deposition process can be physical vapor deposition (PVD) or chemical vapor deposition (CVD). Thus, the first electrically conductive layer 44 can be applied to the internal surface 29 via any one of ionized physical vapor deposition (iPVD), magnetron sputtering, DC sputtering, and evaporation deposition. Similarly, the second electrically conductive layer 46 can be applied to the first electrically conductive layer 44 by a vapor deposition process. For instance, the vapor deposition process can be PVD or CVD. Thus, the second layer 46 can be applied to the first layer via any one of iPVD, magnetron sputtering, DC sputtering, and evaporation deposition.

The second electrically conductive layer 46 can have a thickness greater than the thickness of the first electrically conductive layer 44 along a direction perpendicular to the central axis 31. In one example, the second electrically conductive layer 46 can have a thickness within a range from approximately 200 nm to approximately 5 microns. For instance, the thickness can range from approximately 0.5 micron to approximately 2 microns. The thickness of the first layer 44 can be in a range from approximately 1 nanometer (nm) to approximately 100 nm. For instance, the thickness of the first layer 44 can range from approximately 1 nanometer (nm) to approximately 50 nm. In one example, the thickness can range from approximately 5 nm to approximately 10 nm.

The first electrically conductive layer 44 can extend along the internal surface 29, and can further extend along at least a portion of the first and second external surfaces 22 and 24 of the substrate 20. Thus, the electrically conducive layer 44 can extend along an entirety of the length of the internal surface 29. Alternatively, the first electrically conductive layer 44 can terminate in the hole 26 at a location spaced from either or both of the first and second external surfaces 22 and 24. In this example, the first electrically conductive layer 44 can further extend along either or both of the first and second external surfaces 22 and 24. The first electrically conductive layer 44 can define a material to which the second electrically conductive layer 46 is readily bonded. Further, the first electrically conductive layer 44 can provide a protective layer on the substrate 20 during fabrication of the via 34.

Once the electrically conductive coating 42 has been bonded to the internal surface 29, the fill 40 can be introduced into the hole 26. When the fill 40 is introduced into the hole 26, the hole is defined by the electrically conductive coating 42, and in particular is defined by an inner surface of the electrically conductive coating 42. The fill 40 can be introduced into the hole 26 under vacuum pressure or under positive pressure. For instance, the fill 40 can be placed onto the first surface 22, and negative pressure can be applied to the second end of the hole 26, which causes the fill 40 to be drawn into the hole 26. Alternatively, the fill 40 can be placed into an envelope that is then placed under vacuum to cause the fill 40 to flow into the hole 26. In another example, positive pressure can be applied to the fill 40, which causes the fill to flow into the hole 26. Alternatively still, a squeegee can be driven along the first surface 22, which causes the fill 40 to flow into the hole 26. Methods of causing pastes and other viscous materials to flow into holes in substrates are described in US Publication No. 2023/0005834 published Jan. 5, 2023, and US Publication No. 2019/0304877 published Oct. 3, 2019, the disclosure of each of which is hereby incorporated by reference as if set forth in its entirety herein.

Once the fill 40 is disposed in the hole 26, the substrate can be subjected to heat at a temperature in a range from approximately 125 degrees C to approximately 800 degrees C, depending for instance on whether the fill 40 contains metallic particles that are to be sintered. The substrate 20 can then be actively or passively cooled. It is recognized that the fill material 40 can extend substantially to the first and second external surfaces 22 and 24. When the first electrically conductive material 44 is disposed on the first and second external surfaces 22 and 24, the first electrically conductive material 44 can extend the length of the hole 26, and the fill material 40 can extend to respective outer surfaces of the first electrically conductive material 44 disposed on the first and second external surfaces 22 and 24. The outer surfaces can be planarized, for instance by removing excess material. Excess material can be removed using any suitable polishing process, such as chemical-mechanical polishing (CMP).

Referring again to FIGS. 2A-2B, and as described above, the via 34 can include at least one electrically conductive end cap 45 such as first and second end caps 45a and 45b that extend to the first and second surfaces 22 and 24, respectively, of the substrate 20. The first and second end caps 45a and 45b are spaced from each other along the axial direction that defines the orientation of the central axis 31 of the via 34. In cases where the via 34 includes the first and second end caps 45a and 45b, the first end cap 45a can be in electrical communication with the second end cap 45b by way of the electrically conductive coating 42. In one example, the first end cap 45a can extend substantially to the first external surface 22 of the substrate 20, and the second end cap 45b can extend substantially to the second external surface 24 of the substrate 20. Thus, the first end cap 45a can be substantially flush with the first external surface 22, and the second end cap 45b can be substantially flush with the second external surface 22. Accordingly, a first distance from the first external surface 22 to the second external surface 24 measured along the axial direction can be substantially equal to a second distance from the first outer surface 47a to the second outer surface 47b measured along the axial direction. In some cases, the first end cap 45a, the second end cap 45b, or both, can be devoid of wings that extend over the internal surface 29 in a direction perpendicular to the central axis 31. In some cases, the end cap can be contained entirely within the diameter of the interior surface 29. In some cases, each of the end caps can have a C-shape, defining a leg over the electrically conductive coating 42 that extends along the direction of the central axis and away from a respective terminating end of the hole. Thus, a thickness of the end cap in the defined leg can be greater than the maximum thickness of the region of the end cap that is contained within the diameter of the hole defined by the fill 40. In some cases, an end cap 45a, 45b and the electrically conductive coating 46 can define a first interface 50a, 50b, and the end cap 45a, 45b and the fill 40 can define a second interface. The second interface can be at a location of the fill 40 that faces the internal surface 29 of the substrate 20. The first and second interfaces of the first end cap 45a can be referred to as first and second first end cap interfaces. The first and second interfaces of the second end cap 45b can be referred to as first and second second end cap interfaces. A portion of the first interface 50a, 50b can be opposite the second interface along a direction perpendicular to the central axis. In some cases, the end cap 45a, 45b can define a side region that is disposed outward of the fill 40 in a direction away from the central axis along a direction perpendicular to the central axis. The side region can define a thickness along a direction of the central axis, and the thickness of the side region is at least equal to or greater than a thickness of the end cap 45a, 45b at a location that is aligned with the fill 40 along the direction of the central axis 31. For instance, the side region can define a thickness along a direction of the central axis, and the thickness of the side region is at least equal to or greater than a thickness of the end cap 45a, 45b at the central axis 31, where the thickness of the end cap 45a, 45b is measured along the central axis 31. The thickness of the end cap 45a, 45b can be a maximum thickness of the end cap 45a, 45b at the location that is aligned with the fill 40 along the direction of the central axis. A maximum thickness can be the greatest thickness of the end cap 45a, 45b in the direction of the central axis at any point of the end cap 45, 45b aligned with the fill 40 along the direction of the central axis. The side region of each of the end caps 45a and 45b can be aligned with the layer structure, and can extend over the layer structure at the respective interface 50a, 50b. Without being bound by theory, it is believed that increased thicknesses of the side regions can provide a more robust end cap that can absorb internal gaseous pressure in the respective via during subsequent heating of the substrate after the vias have been formed, for instance when applying a redistribution layer (RDL) to either or both of the first and second surfaces 22 and 24. In some cases, the second end cap 45b can have a thickness greater than the thickness of the first end cap 45a along the direction of the central axis. In some cases, the first and second end caps 45a, 45b can have respective maximum cross-sectional dimensions along a direction perpendicular to the central axis, and the respective maximum cross-sectional dimensions are within 20% of each other, are within 15% of each other, are within 15% of each other, or are within 5% of each other. In some other cases, the maximum cross-sectional dimensions of the end caps 45a, 45b can be substantially equal to each other along the direction of the central axis.

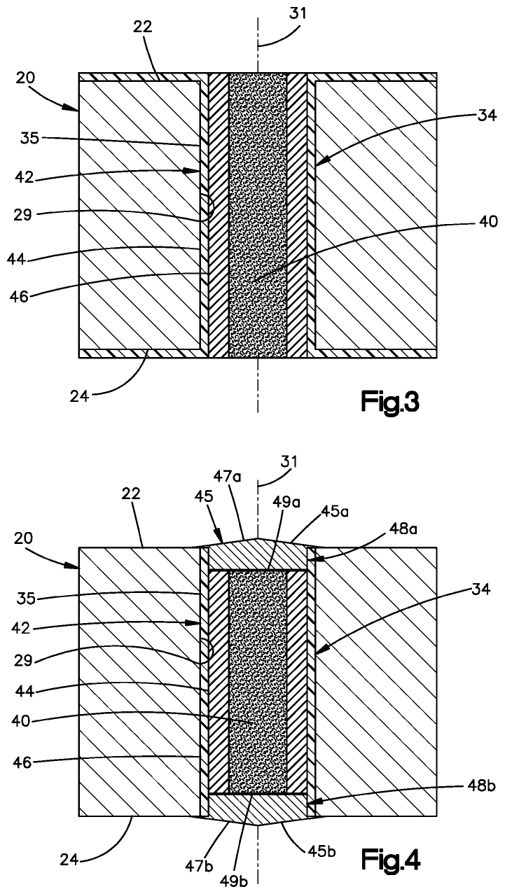

Alternatively, referring to FIG. 4, one or both of the first and second end caps 45a and 45b can extend outward with respect to the first and second external surfaces 22 and 24, respectively. For instance, the first end cap 45a can define a first outer surface 47a that is outwardly offset with respect to the first external surface 22. Similarly, the second end cap 45b can define a second outer surface 47b that is outwardly offset with respect to the second external surface 24. Thus, the first distance from the first external surface 22 to the second external surface 24 measured along the axial direction can be less than the second distance from the first outer surface 47a to the second outer surface 47b measured along the axial direction. Further, the first outer surface 47a can extend beyond the internal surface 29 of the substrate 20 with respect to a direction away from the central axis 31 of the via 34.

Referring again to FIGS. 2A-2B, during fabrication of the via 34, the respective portions of the second layer 46 of the electrically conductive coating 42 and the fill 40 can be removed from the first and second ends of the hole so as to create respective recesses 48a and 48b in the second layer 46 and the fill 40. Thus, the electrically conductive coating 42 and the fill 40 can terminate in the hole 26 at locations recessed from the first and second external surfaces 22 and 24, respectively, of the substrate 20. The respective portions of the second layer 46 and fill 40 can be removed by any suitable mechanical and/or chemical process. In one example, the portions of the second layer 46 and the fill 40 can be removed using mechanical and/or chemical processes, such as chemical-mechanical polishing (CMP). It is recognized that the excess portions of the first layer 44 disposed on the first and second surfaces 22 and 24 can also be removed.

The recesses 48a and 48b, and thus the end caps 45a and 45b, can have any suitable depth in the axial direction. As shown in FIGS. 2A-2B, the respective portions of the second layer 46 and fill 40 can be removed without substantially removing the first layer 44 of the electrically conductive coating 42. Thus, at least portions of the first layer 44 can extend to locations aligned with the recesses 48a and 48b along a direction perpendicular to the central axis 31. This, it can be said that a portion of the electrically conductive coating 42 can extend substantially from the first surface 22 substantially to the second surface 24. The portion of the electrically conductive coating 42 can be defined by the first layer 44. The first layer 44 can thus extend outward in the axial direction with respect to the second layer 46 toward the first surface 22. Further, the first layer 44 can extend outward in the axial direction with respect to the second layer 46 toward the second surface 24. The first layer 44 can thus at least partially define the outer perimeter of the first and second recesses 48a and 48b.

The recesses 48a and 48b can thus extend axially from respective ends of the fill 40 and the second layer 46 to the first and second surfaces 22 and 24, respectively. The recesses 48a and 48b can be bound at their respective perimeters by the first layer 44. It is recognized that some regions of the first layer 44 may be removed during removal of the second layer 46 and the fill 40. Accordingly, the recesses 48a and 48b can, at some localized regions, be defined by the internal surface 29 of the substrate 20. Thus, it can be said that the first layer 44 can at least partially define the outer perimeter of the recesses 48a and 48b.

Once the first and second recesses 48a and 48b have been formed, the first and second end caps 45a and 45b can then be formed in the first and second recesses 48a and 48b, respectively, and bonded one or both of the electrically conductive coating 42 and the to the first layer 44. The first and second end caps 45a and 45b can be applied in the recesses 48a and 48b by a vapor deposition process, such as PVD or CVD. For instance, the first and second end caps 45a and 45b can be formed in the recesses 48a and 48b using iPVD, magnetron sputtering, DC sputtering, and evaporation deposition. The first and second end caps 45a and 45b can be bonded to an internal surface of the first layer 44 that faces the recesses 48a and 48b along a direction perpendicular to the central axis 31. One or both of the first and second end caps 45a and 45b can be directly bonded to the first layer 44, the second layer 46, or both. In some cases, one or both of the first and second end caps 45a and 45b can be bonded to the first layer 44, the second layer 46, or both, by an adhesion layer 49 disposed between the respective end cap and the respective layer(s). The bond between the internal surface of the first layer 44 and the end caps 45a and 45b thus define a respective at least one circumferential line that makes an entire revolution about the central axis in a plane that is substantially perpendicular to the central axis 31. Thus, the end caps 45a and 45b and the first layer 44 can hermetically seal the via 34. Further, the first and second end caps 45a and 45b can be bonded to respective first and second axially outer surfaces of both the second layer 46 that faces the recesses 48a and 48b along the axial direction that is defined by the central axis 31, and the fill 40 that faces the recesses 48a and 48b along the axial direction. Thus, the first and second axially outer surfaces of the second layer 46 and the fill 40 can face the first and second ends of the via 34. If desired, in some examples an adhesion layer can be applied to either or both of the first and second axially outer surfaces of the second layer 46 and the fill 40. For instance, a first adhesion layer 49a can be applied to and bonded to the first axially outer surfaces of the layer structure, such as the second layer 46, and the fill 40. A second adhesion layer 49b can be applied to and bonded to the second axially outer surfaces of the layer structure, such as the second layer 46, and the fill 40. The first and second end caps 45a and 45b can then be bonded to the first and second adhesion layers 49a and 49b, respectively. In this regard, the first and second adhesion layer 49a can be referred to as a first end cap adhesion layer. The second adhesion layer 49b can be referred to as a second end cap adhesion layer. The electrically conductive coating 42 can include the layer structure described above in combination with either or both of the first end cap adhesion layer 49a and the second end cap adhesion layer 49b. In this regard, the fill 40 and either or both of the first and second end caps 45a and 45b can be bonded to the electrically conductive coating 42. Thus, the electrically conductive coating 42 can place the first and second end caps 45a and 45b in electrical communication with each other. In still other examples, the end caps can be bonded directly to the layer structure, such as the second layer 46, without an intervening adhesion layer.

The adhesion layers 49a and 49b can be applied by PVD or CVD as desired. The adhesion layers 49a and 49b can be any suitable metal such as titanium or copper, for instance when the end caps 45a and 45b are copper caps. It should be appreciated, however, that the adhesion layers 49a and 49b can be any one or more of copper, gold, silver, platinum, titanium, aluminum, nickel, tungsten, molybdenum, zinc, barium, boron, palladium, or any suitable alternative material as desired. In some cases, the electrically conductive coating 42 can include one or both of the first and second adhesion layers 49a and 49b. Thus, the electrically conductive coating 42 can include one or more of the first electrically conductive layer, the second electrically conductive layer 44, the first adhesion layer 49a, and the second adhesion layer 49b.

The first and second end caps 45a and 45b can be made of any suitable electrically conductive material as desired. In one example, the first and second end caps 45a and 45b are define by at least one metal. For instance, the first and second end caps 45a and 45b can be made from any one or more of copper, gold, silver, platinum, titanium, aluminum, nickel, tungsten, molybdenum, zinc, barium, boron, palladium, tantalum, a nitride such as titanium nitride and/or tantalum nitride, or any suitable alternative material as desired. It should therefore be appreciated that the first and second end caps 45a and 45b can be the same material as the second layer 46. Alternatively, the first and second end caps 45a and 45b can be the same material as the first layer 46. The first and second end caps 45a and 45b can be the same material as each other. Further, the each of the first and second end caps 45a and 45b can have a respective maximum thickness in a direction that defines the central axis of the electrically conductive via, each respective maximum thickness being no more than 30% of a total length of the electrically conductive via along the direction that defines the central axis, such as no more than 25% of the total length of the electrically conductive via along the direction that defines the central axis, such as no more than 20% of the total length of the electrically conductive via along the direction that defines the central axis, such as no more than 15% of the total length of the electrically conductive via along the direction that defines the central axis, such as no more than 10% of the total length of the electrically conductive via along the direction that defines the central axis. The maximum thickness of the end cap can be defined as a thickness at a location of the respective end cap along the direction, whereby the end cap does not define a thickness greater than the maximum thickness along the direction. The maximum thicknesses of the first and second end caps 45a and 45b along the direction that defines the central axis can be within 30% of each other, such as within 25% of each other, such as within 20% of each other, such as within 15% of each other, such as within 10% of each other, such as within 5 percent of each other, and can be substantially equal to each other.

The end caps 45a and 45b can extend axially from the second layer 42 substantially to the first and second surfaces 22 and 24, respectively. The end caps 45a and 45b can further extend across the fill 40, and thus can extend axially from the fill 40 substantially to the first and second surfaces 22 and 24, respectively. Thus, the second layer 46 and the fill 40 of the via 34 extend from the first end cap 45a to the second end cap 45b. Respective axially inner surfaces of the first and second end caps 45a and 45b can further be adhered or otherwise bonded to the fill 40, and in particular to axially outer ends of the fill 40 in any manner as desired. The first layer 44 can extend substantially from the first surface 22 to the second surface 24. An intermediate portion of the first layer 44 is disposed between the internal surface 29 of the substrate 20 and the second layer 46. First and second outer portions of the first layer 44 are disposed between the internal surface 29 of the substrate 20 and the first and second end caps 45a and 45b, respectively. Excess material of the first and second end caps 45a and 45b can be removed from the first and second surfaces 22 and 24 using any suitable mechanical and/or chemical polishing process if desired.

Referring to FIG. 2B in particular, the via 34 defines at least one interface between the second layer 46 and the at least one end cap 45. For instance, the via 34 defines a first interface 50a between the second layer 46 and the first end cap 45a, and a second interface 50b between the second layer 46 and the second end cap 45b. FIG. 2B shows a SEM image of a first portion of the via 34 including the first surface 22 of the substrate 20, and an inverted reproduction of the SEM image to approximate a second portion of the via 34 including the second surface 24 of the substrate 20. In this regard, the second portion of the via 34 shown in FIG. 2B can be said to be schematic, but representative of the features of the via as described herein.

The interfaces 50a and 50b can be defined by a bond between the second layer 46 and the end caps 45a and 45b. Each of the interfaces 50a and 50b can define an outer region 52 that extends from the first layer 44 toward the central axis 31, and an inner region 54 that extends from the outer region 52 to the fill 40. A boundary between the outer region 52 and the inner region 54 can be disposed substantially at a middle region between the first layer 44 and the fill 40. For instance, the middle region can be a middle third of each of the interfaces 50a and 50b. The outer region 52 can extend in a direction that is substantially perpendicular to the central axis 31. The inner region 54 also extends in an axially inward direction as it extends from the outer region 52 to the fill 40. Accordingly, an inner interface between the inner region 54 and the fill 40 is offset with respect to an outer interface between the outer region 52 and the first layer 29 in the axially inward direction. The inner region 54 can flares toward the surface 22 as it extends towards the layer 44. The outer region 52 can extend from the inner region 54 to the internal surface 29, or alternatively towards an adhesion layer disposed on the internal surface 29. The outer region 52 can form an angle with the inner region 54 that is greater than 90 degrees and less than 180 degrees, greater than 95 degrees and less than 180 degrees, greater than 100 degrees and less than 170 degrees, and the like. The axially inward direction is a direction toward an axial midline that is substantially equidistantly spaced between the first and second surfaces 22 and 24. Thus, the axially inward direction of the first interface 50a is directed toward the second surface 24, and the axially inward direction of the second interface 50b is directed toward the first surface 22.

The first end cap 45a can define a respective first depth along the axial direction from the first external surface 22 of the substrate 20, or the first end of the via 45, to the second interface 50b or the fill 40, and a respective second depth along the axial direction from the first external surface 22 of the substrate 20, or the first end of the via 34, to the outer region 52 of the first interface 50a or the layer structure. The second depth can be defined at an end of the first end cap 45a, where the end is defined with respect to an outward direction that extends away from the central axis 31 along a direction perpendicular to the central axis 31. The respective second depth can be within approximately 50% of the respective first depth, such as within approximately 75% of the respective first depth, such as substantially equal to the respective first depth. Thus, it can also be said that the first end cap 45a can define a respective first depth along the axial direction from the first external surface 22 of the substrate 20, or the first end of the via 45, to the fill 40, and a respective second depth along the first layer 44 along the axial direction that is within approximately 50% of the respective first depth, such as within approximately 75% of the respective first depth, such as substantially equal to the respective first depth. The respective first and second depths can be in a range from approximately 1 micron to approximately 10 microns, such as from approximately 2 microns to approximately 4 microns along the axial direction.

Similarly, the second end cap 45b can define a respective first depth along the axial direction from the second external surface 24 of the substrate 20, or the second end of the via 45, to the second interface 50b or the fill 40, and a respective second depth along the axial direction from the second external surface 24 of the substrate 20, or the second end of the via 45, to the outer region 52 of the first interface 50a or the layer structure. The second depth can be defined at an end of the second end cap 45b, where the end is defined with respect to an outward direction that extends away from the central axis 31 along a direction perpendicular to the central axis 31. The respective second depth can be within approximately 50% of the respective first depth, such as within approximately 75% of the respective first depth, such as substantially equal to the respective first depth. Thus, it can also be said that the second end cap 45b can define a respective first depth along the axial direction from the second external surface 24 of the substrate 20, or the second end of the via 45, to the fill 40, and a respective second depth along the first layer 44 along the axial direction that is within approximately 50% of the respective first depth, such as within approximately 75% of the respective first depth, such as substantially equal to the respective first depth. The respective first and second depths can be in a range from approximately 1 micron to approximately 10 microns, such as from approximately 2 microns to approximately 4 microns along the axial direction. Thus, the respective first and second depths of the first end cap 45a can be substantially equal to the respective first and second depths of the second end cap 45b.

A first straight line 56 oriented along a direction that is substantially perpendicular to the central axis 31 can be defined that extends through the internal surface 29 of the substrate 20, the first layer 44, the second layer 46, the first end cap 45a, and the fill 40. For instance, the first straight line 56 can extend across the inner region 54 of the first interface 50a. Similarly, a second straight line 58 oriented along a direction that is substantially perpendicular to the central axis 31 can be defined that extends through the internal surface 29 of the substrate 20, the first layer 44, the second layer 46, the second end cap 45b, and the fill 40. For instance, the second straight line 58 can extend across the inner region 54 of the second interface 50b.

An example fabrication process for vias is described below. The holes 26 of the substrate 20 can be created, for instance, by laser ablation. Alternatively, the substrate 20 can be provided with the holes 26 preformed. Next, the coating 42 can be applied to the substrate 20. In particular, the first electrically conductive layer 44 can be applied to the internal surface 29, and optionally either or both of the first and second surfaces 22 and 24, by a vapor deposition process. For instance, the vapor deposition process can be PVD or CVD. Thus, the first electrically conductive layer 44 can be applied to the internal surface 29 via any one of iPVD, magnetron sputtering, DC sputtering, and evaporation deposition. In some cases, the first electrically conductive layer 44 can include titanium, tantalum, titanium tungsten, chromium, molybdenum, titanium nitride, tantalum nitride, and the like. Further, the vapor deposition process can result in the electrically conductive layer 44 being partially porous, with the material of the first electrically conductive layer 44 being unevenly deposited along the internal surface 29.

Next, the second electrically conductive layer 46 can be deposited on the first electrically conductive layer 44 by a vapor deposition process. For instance, the vapor deposition process can be PVD or CVD. Thus, the first electrically conductive layer 44 can be applied to the internal surface 29 via any one of iPVD, magnetron sputtering, DC sputtering, and evaporation deposition. In some cases, the second electrically layer 46 can include copper. Further, as the copper is deposited via vapor deposition, the copper can be porous (similar to the first electrically conductive layer 44). Some of the copper can enter crevices formed by the first electrically conductive layer (e.g. due to the vapor phase deposition), thereby adhering the vapor phased copper to the first electrically conductive layer.

Next, an additional layer of material can be deposited on the second electrically conductive layer 46. This additional layer can in some cases be considered part of the second electrically conductive 46. In other cases, the additional layer can be considered to be a third electrically conductive layer. The additional layer can be copper in some cases. Further, the additional layer can be plated onto the vapor phase deposited copper. For example, the substrate 20 can be submerged or placed in an electrolytic liquid, and a current is passed through the liquid. The current can cause copper ions to migrate and deposit on the vapor phase deposited copper. The copper plating can hermetically seal the interior surface 29 of the substrate 20 from the remaining cavity of the via hole 26, and any fill 40 placed in the via hole.

Next, the fill 40 can be deposited into the via hole 26. When the fill 40 is introduced into the hole 26, the hole is defined by the electrically conductive coating 42, and in particular is defined by an inner surface of the electrically conductive coating 42. The fill 40 can be introduced into the hole 26 under vacuum pressure or under positive pressure. For instance, the fill 40 can be placed onto the first surface 22, and negative pressure can be applied to the second end of the hole 26, which causes the fill 40 to be drawn into the hole 26. Alternatively, the fill 40 can be placed into an envelope that is then placed under vacuum to cause the fill 40 to flow into the hole 26. In another example, positive pressure can be applied to the fill 40, which causes the fill to flow into the hole 26. Alternatively still, a squeegee can be driven along the first surface 22, which causes the fill 40 to flow into the hole 26. The fill 40 can have a thickness, in a direction perpendicular or parallel to the central axis, that is at least 10 to at least 50 microns thicker than a maximum thickness of the endcap in the direction of the central axis.

Once the fill 40 is disposed in the hole 26, the substrate can be subjected to heat at a temperature in a range from approximately 125 degrees C to approximately 800 degrees C, depending for instance on whether the fill 40 contains metallic particles that are to be sintered. The substrate 20 can then be actively or passively cooled. It is recognized that the fill material 40 can extend substantially to the first and second external surfaces 22 and 24. When the first electrically conductive material 44 is disposed on the first and second external surfaces 22 and 24, the first electrically conductive material 44 can extend the length of the hole 26, and the fill material 40 can extend to respective outer surfaces of the first electrically conductive material 44 disposed on the first and second external surfaces 22 and 24.

In some cases, the materials deposited into the hole 26 can then undergo material removal processes to planarize the external surfaces 22, 24, and/or to remove material in preparation for depositing of the end cap(s). For example, the materials of the hole 26 can undergo a CMP process, which can remove an amount of the copper of the second electrically conductive layer 46. In some cases, the materials of the hole 26 can undergo wet etching, which can deposit a copper etchant (e.g., peroxysulfate) onto the materials of the hole 26 and remove an amount of the copper of the second electrically conductive layer 46. In some cases, the etching process can be performed after the depositing of the second electrically conductive material 44. In some cases, both CMP and wet etching can be used, for example, performing a CMP process after wet etching. Further, the fill 40 can also undergo a CMP process (e.g., an epoxy CMP), which can remove some of the material of the fill 40. The etching can in some cases can allow for a thicker end cap to be applied to the via, as etching can remove more material of the first electrical conductive layer, the second electrical conductive layer, or both, as compared to polishing the electrically conducive layers, which may be limited in the depth of the layer removal by the length of the substrate, the length of the fill, or both. Further, in some cases, the via is not be a capacitor.

Next, the end caps 45a, 45b can be deposited into the hole 26. The end caps 45, 45b can be placed into the hole 26 by vapor deposition process. For instance, the vapor deposition process can be PVD or CVD. Thus, the second layer 46 can be applied to the first layer via any one of iPVD, magnetron sputtering, DC sputtering, and evaporation deposition. In some cases, an adhesive layer is placed in the hole 26 (e.g., adhesion layer 49) prior to depositing the end cap 45a, 45b into the hole 26. In some cases, the end cap 45a, 45b can be planarized or material removed, such as by a CMP process. Planarizing the end cap can result in better electrical communication with a RDL deposited onto the end cap. Once the end cap is deposited, a RDL can be deposited onto the end cap.

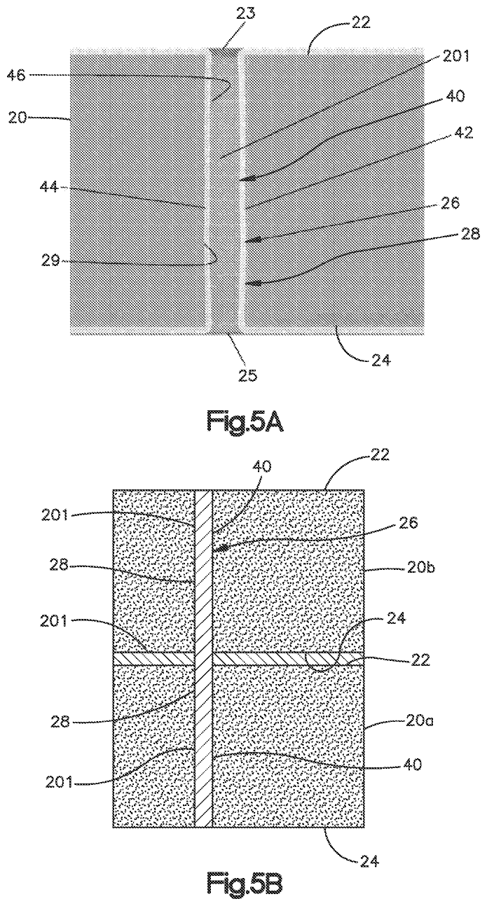

Referring now to FIG. 5A, and as described above, it is recognized that the fill material 40 can be alternatively configured as desired. In one example, the fill material 40 can be electrically nonconductive. Further, the fill material 40 can be a glass composite material 201 that can be introduced into the hole 26 after the layer structure has been disposed on the internal surface 29 as described above, and subsequently sintered. Thus, the glass composite material 201 can be surrounded by the layer structure in a plane oriented perpendicular to the central axis of the via. The glass composite material 201 can be introduced into the hole 26 in a viscous state, and subsequently solidified to a solid state so as to produce solidified glass composite material, or solidified glass material, that occupies at least a portion up to an entirety of a reminder of the hole 26 as defined by the layer structure. For instance, the glass composite material 201, and thus the solidified glass composite material 201, can extend at least 75%, such as at least 80%, such as at least 85%, such as at least 90%, such as at least 95% of the length of the hole 26, and thus of the resulting via, whereby the length is defined along a direction that is defined by the central axis of the hole 26 and thus of the via. The solidified glass composite material 201 is separate from the glass substrate 20, but can be the same material as the glass substrate 20. Alternatively, the solidified glass composite material 201 can be a different material than the glass substrate 20. The coating 42 can define a layer structure of the type described above. Thus, the second electrically conductive layer 46 can be bonded to the first electrically layer 44 which, in turn, is bonded to the internal surface 29 in the manner described above. The solidified glass composite material 201 can thus abut the coating 42, and can be bonded to the coating. In particular, the solid glass composite material can abut the second electrically conductive layer 46, and can be bonded to the second electrically conductive layer 46. Alternatively, the coating 42 can include the first electrically conductive layer 44 and not the second electrically conductive layer 46, such that the solidified glass composite material 201 is bonded to the first electrically conductive layer 44. Alternatively still, the coating 42 and thus the layer structure can include the first electrically conductive layer 44 disposed between the internal surface 29 and the second electrically conductive layer 46 in the manner described above, and can further include the first electrically conductive layer 44 disposed between the second electrically conductive layer 46 and the solidified glass composite material 201.

Advantageously, the glass composite material 201 can have a glass coefficient of thermal expansion (CTE) close to glass, such that sintering the glass composite material 201 inside the hole 26 does not affect the structural integrity of the substrate 20, which can be a glass substrate as described above. For instance, the CTE of the glass composite material 201 can be closer to the CTE of glass than the CTE of epoxy is to the CTE of glass. Further, the glass composite material is more stable than fritted paste.

In one example, the glass composite material 201 can be a Glassomer® nanocomposite commercially available from Glassomer GmbH having a principal place of business in Freiburg, Germany.

During fabrication of the via, the coating 42 is applied to the internal surface 29 in the manner described above. Subsequently, the glass composite material 201 in a viscous state can be introduced into the hole 26 so as to fill the remaining portion of the hole 26 not occupied by the coating 42 or layer structure. For instance, the glass composite material 201 can be driven into the hole 26 under negative pressure forces, positive pressure forces, by squeegee, or any suitable alternative method as desired. Once the glass composite material 201 has been introduced into the hole 26, the glass composite material 201 can be UV cured in a curing step, debound in a debinding step, and sintered in a sintering step. It can thus be said that the glass composite material 201 is UV curable. After the viscous glass composite material 201 has been introduced into the hole, the glass composite material 201 can be cured under ultraviolet light (UV-A) at 365 nm. In some examples, a single application of ultraviolet light can cure an entire desired volume of the glass composite material 201 that has been introduced into the hole 26. In one example, the desired volume of glass composite material 201 can substantially or entirely fill the hole 26. Alternatively, the hole 26 can be iteratively filled with the glass composite material 201 by incrementally introducing the glass composite material 201 into the hole 26 and UV curing the glass composite material 201 at each increment until the desired volume of glass composite material 201 has been introduced into the hole 26 and cured. The solidified glass composite material can be substantially cylindrical.

Once the glass composite material has been cured, the glass composite material can be debound in a thermal debinding process to remove impurities, such as volatile organic compounds (VOCs). The debinding process can remove substantially all impurities from the glass composite material. In one example, the debinding process can remove an organic binder matrix from the glass composite material. The debinding process can be performed by heating the glass composite material to 600 C. Thus, the substrate 20 can be placed in an oven and baked at any suitable debinding temperature until the glass composite material 201 has been debound. The debinding temperature can be in a range from approximately 200 C to approximately 1000 C, such as from approximately 400 C to approximately 800 C, such as from approximately 500 C to approximately 700 C, such as approximately 600 C. After the debinding process has been performed, the glass composite material can be sintered at any suitable sintering temperature, which can be in a range from approximately 1000 C to approximately 1500 C, such as from approximately 1200 C to approximately 1400 C, such as approximately 1300 C. The sintering can occur under vacuum or at atmospheric pressure. After sintering has been completed, the resulting solidified glass composite material 201 can define transparent glass. In one example, the glass composite material can define transparent fused silica glass. It should be appreciated that the debinding and sintering temperatures of the glass composite material can be less than the glass transition temperature of silica glass, which can be advantageous when the substrate 20 is a silica glass substrate 20.

It is recognized that the via produced by the coating 28 and the solidified composite glass material 201 can be devoid of either or both of the first end cap and the second end cap described above. Thus, the solidified glass composite material 201 can be open to either or both of the first opening 23 and the second opening 25. Alternatively, the via can further include either or both of a first end cap and a second end cap. The first end cap extends over a first terminal end of the solidified glass composite material 201, and the second end cap extends over a second terminal end of the solidified glass composite material 201 that is opposite the first terminal end along a direction that defines the central axis of the via. Each cap can extend across an entirety of the hole 26 along a direction perpendicular to the direction that defines the central axis, and can be bonded with the layer structure in the manner described above.

Referring now to FIG. 5B, it is recognized that the glass composite material 201 can also join first and second substrates 20 to each other so as to define a composite structure. In particular, the glass composite material can be placed onto a first surface of a first glass substrate 20a. Alternatively or additionally, the glass composite material can be placed onto a second surface of a second glass substrate 20b. The first and second surfaces of the first and second glass substrates 20a and 20b can then be placed over each other, such that the glass composite material extends from the first surface to the second surface. The first and second surfaces can be defined by respective ones of surfaces 22 and 24 of the substrates 20a and 20b, or any suitable alternative external surfaces as desired. The glass composite material can then be UV cured, debound, and sintered in the manner described above to bond the first substrate 20a to the second substrate 20b. Thus, first and second glass substrates 20a and 20b can thus be bonded to each other by solid glass defined by the solidified glass composite material 201. The electrically conductive vias of the first and second substrates 20a and 20b can be aligned with each other along the transverse direction, and can be placed in electrical communication with each other, or can be electrically insulated from each other. Alternatively still, the vias of the first and second substrates 20a and 20b can be offset from each other along a direction perpendicular to the central axis of each of the vias. The solidified glass composite material between the substrates 20a and 20b can extend to either or both of the vias as shown, or can terminate at a location spaced from the vias.

It should be appreciated that the illustrations and discussions of the embodiments shown in the figures are for exemplary purposes only, and should not be construed limiting the disclosure. One skilled in the art will appreciate that the present disclosure contemplates various embodiments. Additionally, it should be understood that the concepts described above with the above-described embodiments may be employed alone or in combination with any of the other embodiments described above. It should be further appreciated that the various alternative embodiments described above with respect to one illustrated embodiment can apply to all embodiments as described herein, unless otherwise indicated.

1-56. (canceled)

57. A method of fabricating an electrical via in a hole of a substrate, wherein the hole defines opposed terminating ends opposite each other along a central axis, the method comprising:
depositing a first electrical layer along an interior surface of a substrate, wherein the interior surface defines the hole;
depositing a second electrical layer along the first electrical layer, such that the first electrical layer is disposed between the interior surface and the second electrical layer;
filling a remaining portion of the hole with a fill, wherein the remaining portion of the hole is at least partially defined by the second electrical layer;
removing a portion of the second electrical layer so as to produce a void that extends along the fill to one of the terminating ends of the hole; and
depositing a third conductive layer into the void so as to form an end cap, thereby sealing the fill deposited in the hole.

58. The method of claim 57, wherein the first electrical layer comprises titanium, tantalum, titanium tungsten, chromium molybdenum, titanium nitride, or tantalum nitride.

59. The method of claim 57, wherein the first electrical layer is deposited via vapor deposition.

60. The method of claim 57, wherein the second electrical layer comprises copper.

61. The method of claim 57, wherein the second electrical layer is deposited via vapor deposition.

62. The method of claim 57, further comprising depositing a fourth electrical layer along the second electrical layer, such that the second electrical layer is disposed between the first electrical layer and the fourth electrical layer, and wherein the fourth electrical layer is deposited via a plating process.

63-70. (canceled)

71. The method of claim 57, further comprising:
after filling the hole with the fill, heating the fill to cure the fill.

72. The method of claim 57, wherein the removing the portion of the second electrical layer comprises performing a chemical-mechanical polishing process on the second electrical layer.

73. The method of claim 57, wherein the removing the portion of the second electrical layer comprises performing a wet etching process on the second electrical layer.

74. The method of claim 57, further comprising:
removing a portion of the fill adjacent to the terminating end of the hole.

75. The method of claim 57, wherein removing the portion of the fill comprises performing a chemical-mechanical polishing (CMP) process on the fill.

76. The method of claim 57, further comprising:
applying an adhesive layer into the void of the hole prior to depositing the end cap.

77. The method of claim 76, wherein the adhesive layer comprises titanium, tantalum, titanium tungsten, chromium molybdenum, titanium nitride, or tantalum nitride.

78. The method of claim 76, wherein the adhesive layer is applied by vapor deposition.

79. The method of claim 57, further comprising removing a portion of the end cap after deposition.

80. The method of claim 79, wherein removing the portion of the end cap is performed by a chemical-mechanical polish (CMP) process.

81. The method of claim 79, wherein removing the portion of the end cap comprises planarizing the end cap.

82. The method of claim 57, further comprising depositing a redistribution layer (RDL) atop the end cap.

83. The method of claim 57, further comprising:
removing a second portion of the second electrical layer so as to produce a second void that extends along the fill to the other of the terminating ends of the hole; and
depositing a fifth conductive layer into the second void so as to form a second end cap, thereby sealing the fill deposited in the hole.

84. The method of claim 57, wherein the filling step comprises driving a viscous composite glass material into the remaining portion of the hole, UV-curing the viscous composite glass material, debinding the substrate including the composite glass material, and sintering the composite glass material.

85-105. (canceled)
